(19) United States
(12) Patent Application Publication
(10) Pub. No.: US 2026/0028709 A1
(43) Pub. Date: Jan. 29, 2026

(54) DEPOSITION APPARATUS AND METHOD OF MAINTAINING THE SAME

(71) Applicants: Samsung Display Co., LTD., Yongin-si, Gyeonggi-do (KR); ULVAC, Inc., Chigasaki-shi, Kanagawa (JP)

(72) Inventors: KYUNGHOON CHUNG, Yongin-si (KR); SHINJIRO KURAHASHI, Chigasaki-shi (JP); HIDEKI IIJIMA, Chigasaki-shi (JP); KAZUHIKO KOIZUMI, Chigasaki-shi (JP); JUNGSEOB LEE, Yongin-si (KR); YONGSIC JEON, Yongin-si (KR); HYEONSIK KIM, Yongin-si (KR); YONG YEO, Yongin-si (KR)

(21) Appl. No.: 19/046,195

(22) Filed: Feb. 5, 2025

(30) Foreign Application Priority Data
Jul. 26, 2024 (KR) 10-2024-0099211

(51) Int. Cl. C23C 14/24

(52) U.S. Cl. CPC C23C 14/24

(57) ABSTRACT

A deposition apparatus includes a process chamber that provides a space to process a substrate, and including a side surface in which an opening is defined, a door configured to open or close the opening of the process chamber, and a deposition source configured to supply a deposition material to the substrate in the process chamber, and including an upper surface of which at least a portion is exposed through the opening when the opening is opened by the door.

### CROSS-REFERENCE TO RELATED APPLICATION

The present application claims priority to and the benefit of Korean Patent Application No. 10-2024-0099211, filed on Jul. 26, 2024, in the Korean Intellectual Property Office, the entire content of which is hereby incorporated by reference.

### BACKGROUND

### 1. Field

Embodiments of the present disclosure relate to a deposition apparatus and a method of maintaining the same. For example, embodiments of the present disclosure relate to a deposition apparatus for vacuum deposition and a method of maintaining the same.

### 2. Description of the Related Art

A manufacturing process of a semiconductor or display device may include a vacuum deposition method that forms a thin film on a deposition target. The vacuum deposition method may be a method in which a substrate, which is a deposition target, and an evaporation source including a raw material for deposition particles are provided in a chamber, and the evaporation source is heated to vaporize the raw material, thereby evaporating and spraying the raw material to form the thin film on one surface of the substrate.

Recently, as a size of the substrate, which is a deposition target, has become larger, a size of a deposition apparatus for depositing on the deposition target has also become larger. Accordingly, components included in the large deposition apparatus have also become larger and heavier, so that in order to perform maintenance work on the deposition apparatus, there is a difficulty that a worker has to go inside the deposition apparatus directly to resupply the raw material and/or directly to remove components that need to be replaced.

### SUMMARY

Embodiments of the present disclosure provide a deposition apparatus that is easy to maintain.

Embodiments provide a method of maintaining the deposition apparatus.

A deposition apparatus according to an embodiment includes a process chamber that provides a space to process a substrate, and including a side surface in which an opening is defined, a door configured to open or close the opening of the process chamber, and a deposition source configured to supply a deposition material to the substrate in the process chamber, and including an upper surface of which at least a portion is exposed through the opening when the opening is opened by the door.

In an embodiment, the deposition apparatus may further include a door driver configured to move the door.

In an embodiment, the door driver may open or close the opening by rotating the door.

In an embodiment, the door driver may open or close the opening by sliding the door.

In an embodiment, a first contact surface of the process chamber adjacent to the opening may contact a second contact surface of the door when the opening is closed by the door.

In an embodiment, each of the first contact surface and the second contact surface may be inclined obliquely with respect to a normal direction of the substrate, in a cross-sectional view.

In an embodiment, a concave groove concaved from the second contact surface toward an inside of the door may be defined in the door.

In an embodiment, the concave groove and the opening may be connected to each other when the opening may be closed by the door.

In an embodiment, a width of the door may decrease from an upper portion of the door to a lower portion of the door, in a cross-sectional view.

In an embodiment, a width of the process chamber may increase from an upper portion of the process chamber to a lower portion of the process chamber, in a cross-sectional view.

In an embodiment, the deposition apparatus may further include a source moving part configured to move the deposition source in a direction parallel (e.g., substantially parallel) to the substrate in the process chamber

In an embodiment, the source moving part may move the deposition source toward the door when the opening is opened by the door.

A deposition apparatus according to an embodiment includes a process chamber that provides a space to process a substrate, and including a side surface in which an opening is defined, a door configured to open or close the opening of the process chamber, and having a width which gradually decreases from an upper portion of the door to a lower portion of the door in a cross-sectional view, and a deposition source configured to supply a deposition material to the substrate in the process chamber.

In an embodiment, a width of the process chamber may increase from an upper portion of the process chamber to a lower portion of the process chamber.

In an embodiment, at least a portion of an upper surface of the deposition source may be exposed through the opening when the opening is opened by the door.

A method of manufacturing a deposition apparatus according to an embodiment includes moving a deposition source configured to supply a deposition material to a substrate in a process chamber toward a door contacting a side surface of the process chamber, opening an opening defined in the one side surface of the process chamber by using the door, and replacing a target object provided in the process chamber through the opening at an outside of the process chamber.

In an embodiment, in the opening of the opening the door may be opened so that a center portion of the deposition source is exposed.

In an embodiment, in the moving of the deposition source toward the door, the deposition source may be moved in a direction parallel (e.g., substantially parallel) to the substrate using a source moving part coupled to the deposition source, and in the opening of the opening, the source moving part may support the center portion of the deposition source.

In an embodiment, in the opening of the opening, the opening may be opened by rotating the door.

In an embodiment, in the opening of the opening, the opening may be opened by sliding the door.

In a deposition apparatus according to embodiments of the present disclosure, a door may open and close an opening defined on a side surface of a process chamber. In embodiments, when the door opens the opening, a deposition source may be exposed through the opening. Accordingly, when performing maintenance work on the deposition apparatus, a worker may easily perform the maintenance work periodically from an outside the process chamber, so that an efficiency of the maintenance work on the deposition apparatus may be improved.

In embodiments, because a guide rail, a moving cart, and/or the like, for accessing the process chamber are not required separately, an efficiency of the maintenance work on the deposition apparatus may be further improved, and a maintenance work time may be shortened.

In embodiments, in a cross-sectional view, the door may have a width that decreases from an upper portion of the door to a lower portion of the door, and the process chamber may have a width that increases from an upper portion of the process chamber to a lower portion of the process chamber. Accordingly, because the opening is easily opened and closed using the door, an efficiency of the maintenance work on the deposition apparatus may be further improved.

In a method of maintaining the deposition apparatus according to embodiments of the present disclosure, the deposition source may be moved toward the door so that the center of the deposition source is exposed by the opening, and a target object provided in the process chamber may be replaced from the outside of the process chamber. Accordingly, the worker may perform maintenance work at the outside of the process chamber without directly entering an inside of the process chamber, so that the efficiency of the maintenance work of the large-scale deposition apparatus may be improved. In embodiments, a gas mask, a gas suit, and/or the like, that are worn by the worker when entering the inside of the process chamber while performing the method are not separately required. Accordingly, maintenance cost and time maybe reduced through the method according to embodiments of the present disclosure.

### BRIEF DESCRIPTION OF THE DRAWINGS

Illustrative, non-limiting embodiments of the present disclosure will be more clearly understood from the following detailed description in conjunction with the accompanying drawings.

FIG. 1 is a perspective view illustrating a deposition apparatus according to an embodiment of the present disclosure.

FIG. 2 is a perspective view illustrating the deposition apparatus of FIG. 1 having a closed door.

FIG. 3 is a cross-sectional view illustrating a cross-section taken along a line I-I′ of FIG. 2.

FIG. 4 is a cross-sectional view illustrating a cross-section taken along a line II-II′ of FIG. 2.

FIG. 5 is a plan view illustrating a portion of the deposition apparatus of FIG. 1.

FIG. 6 is a flow chart illustrating an embodiment of a method of maintaining the deposition apparatus of FIG. 1.

FIG. 7 is a cross-sectional view illustrating a moving of the deposition source toward the door.

FIG. 8 is a plan view illustrating an opening of the opening by rotating the door.

FIG. 9 is a perspective view illustrating a replacing of the target object provided in the process chamber at the outside of the process chamber.

FIG. 10 is a perspective view illustrating a portion of a deposition apparatus according to another embodiment of the present disclosure.

FIG. 11 is a flow chart illustrating an embodiment of a method of maintaining the deposition apparatus of FIG. 10.

FIG. 12 is a plan view illustrating an opening of the opening by sliding the door.

### DETAILED DESCRIPTION

The subject matter of the present disclosure now will be described more fully hereinafter with reference to the accompanying drawings, in which embodiments of the present disclosure are shown. The subject matter of the present disclosure may, however, be embodied in many different forms and should not be construed as limited to the embodiments set forth herein.

Rather, these embodiments are provided so that this disclosure will be thorough and complete, and will fully convey the scope of the present disclosure to those skilled in the art. Like reference numerals refer to like elements throughout.

It will be understood that, although the terms first, second, third, and the like, may be used herein to describe various elements, components, areas, layers and/or sections, these elements, components, areas, layers and/or sections should not be limited by these terms. These terms are only used to distinguish one element, component, area, layer or section from another area, layer or section. Thus, a first element, component, area, layer or section discussed below could be termed a second element, component, area, layer or section without departing from the spirit and scope of the present disclosure.

The terminology used herein is for the purpose of describing example embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein may be performed in a suitable order unless otherwise indicated herein or otherwise clearly contradicted by context. The use of any and all examples, or exemplary language (e.g., “such as”), is intended merely to better illustrate the subject matter of the disclosure and does not pose a limitation on the scope of the disclosure unless otherwise claimed. No language in the specification should be construed as indicating any non-claimed element as essential to the practice of the present disclosure as used herein.

Hereinafter, apparatuses and methods in accordance with embodiments will be described in more detail with reference to the accompanying drawings. The same reference numerals are used for the same components in the drawings, and redundant descriptions of the same components may not be repeated.

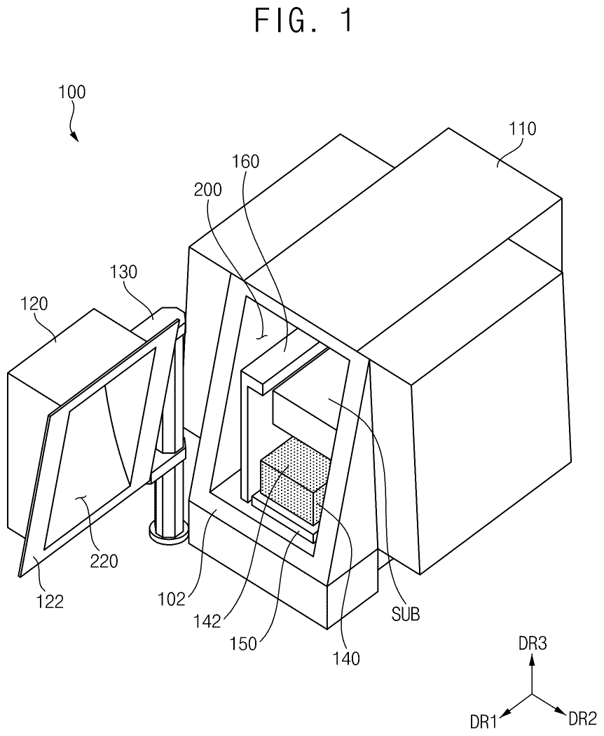

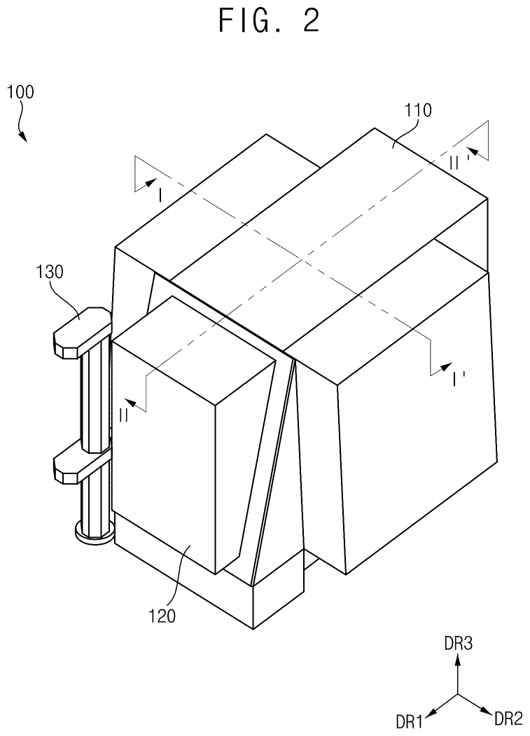

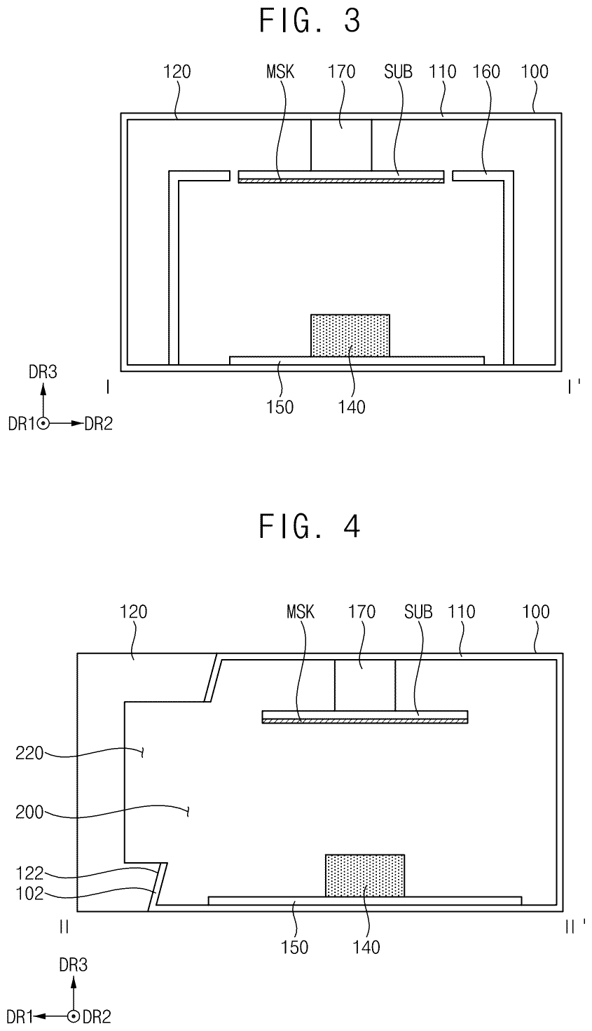

FIG. 1 is a perspective view illustrating a deposition apparatus according to an embodiment of the present disclosure. FIG. 2 is a perspective view illustrating the deposition apparatus of FIG. 1 having a closed door. FIG. 3 is a cross-sectional view illustrating a cross-section taken along a line I-I′ of FIG. 2. FIG. 4 is a cross-sectional view illustrating a cross-section taken along a line II-II′ of FIG. 2.

Referring to FIGS. 1-4, a deposition apparatus 100 may include a process chamber 110, a door 120, a door driver 130, a deposition source 140, a source moving part 150, an adhesion preventing plate 160, and a fixing part 170.

In this specification, a plane may be defined by a first direction DR1 and a second direction DR2. For example, the first direction DR1 and the second direction DR2 may be perpendicular (e.g., substantially perpendicular) to each other. In embodiments, a third direction DR3 may be perpendicular (e.g., substantially perpendicular) to the plane.

The deposition apparatus 100 may be used in a deposition process to deposit a deposition material on a deposition target (e.g., a substrate SUB). The deposition apparatus 100 may maintain a vacuum state inside the deposition apparatus while the deposition process is in progress. For example, the inside of the process chamber 110 may be maintained in a vacuum state while the deposition process is in progress. In an embodiment, the deposition apparatus 100 may be a large-scale deposition apparatus for performing the deposition process.

The deposition process may include a process of heating a raw material contained in the deposition source 140, and the heated raw material vaporizes and moves toward the substrate SUB to be deposited on the deposition target. The raw material may be in a liquid state or in a solid state. The substrate SUB on which the deposition material is deposited may be used in the manufacture of a semiconductor device and/or a display device. The deposition material may be a thin film deposited on a semiconductor device or a display device. For example, the deposition material may include an organic material that forms a light-emitting layer of the display device. However, types (or kinds) of the deposition material according to the embodiments of the present disclosure may not be limited thereto, and the deposition material may form an electrode layer, a metal layer, an inorganic insulating layer (e.g., an inorganic electrically insulating layer), an organic insulating layer (e.g., an organic electrically insulating layer), and/or the like, included in the display device.

The deposition process performed in the deposition apparatus 100 may include a vacuum deposition method, a physical vapor deposition (PVD) method such as an ion plating, sputtering, a chemical vapor deposition (CVD) method by gas reaction, and/or the like.

A mask MSK may be provided between the deposition source 140 and the substrate SUB. The deposition material may pass through the mask MSK and be deposited on the substrate SUB. An opening having a set or specific pattern is formed in the mask MSK, and the deposition material may have a pattern corresponding to the pattern of the mask MSK and be deposited on the substrate SUB. In embodiments, the mask MSK may include an alignment member. The alignment member may fix the substrate SUB to a set or specific position on the mask MSK so that the substrate SUB corresponds to the pattern of the mask MSK.

The process chamber 110 may provide a space in which to process the substrate SUB. In an embodiment, the process chamber 110 may include a metal material. However, a material included in the process chamber 110 according to embodiments of the present disclosure may not be limited thereto, and the process chamber 110 may include various suitable materials such as a rigid plastic.

The process chamber 110 may be maintained in a vacuum state when the deposition process is performed. The process chamber 110 may include a vacuum pump (e.g., a turbomolecular pump, an oil diffusion vacuum pump, and/or the like) to maintain a vacuum state in the process chamber 110. For example, the vacuum pump may serve to discharge air inside the process chamber 110 to an outside of the process chamber 110 to maintain the inside of the process chamber 110 in a vacuum state. The vacuum pump may be provided outside or inside the process chamber 110.

An opening 200 that is connected to the space may be defined on (a side surface (e.g., an one side surface) of the process chamber 110. In an embodiment, a width of the process chamber 110 may increase from an upper portion of the process chamber 110 to a lower portion of the process chamber 110 in a cross-sectional view (e.g., a direction from an upper portion to a lower portion being defined by the third direction DR3). For example, a width of the upper portion of the process chamber 110 in the first direction DR1 may be smaller than a width of the lower part of the process chamber 110 in the first direction DR1. In some embodiments, the cross-section may be a cross-section that includes the opening 200 and cuts the process chamber 110 along a line parallel to the first direction DR1. For example, the process chamber 110 may have a shape of an upper-narrow and a lower-wide in which the width of the upper portion is greater than the width of the lower portion.

A first contact surface 102 that contacts the door 120 may be defined in the process chamber 110. For example, the first contact surface 102 may be a portion of the process chamber 110 adjacent to the opening 200. In an embodiment, the first contact surface 102 may be inclined obliquely with respect to a normal direction perpendicular (e.g., substantially perpendicular) to the substrate SUB (e.g., the third direction DR3). For example, a direction in which the first contact surface 102 is inclined may be a diagonal direction between an opposite direction of the first direction DR1 and the third direction DR3.

The door 120 may open and close the opening 200. For example, the door 120 may open the opening 200 by being spaced apart from the side surface (e.g., the one side surface) of the process chamber 110. In some embodiments, the door 120 may close the opening 200 by coming into contact with the side surface (e.g., the one side surface) of the process chamber 110. As the door 120 opens the opening 200, a worker may perform maintenance work on the components (e.g., the deposition source 140, the adhesion protecting plate 160) in the process chamber 110.

A second contact surface 122 that contacts the process chamber 110 may be defined on the door 120. For example, the second contact surface 122 of the door 120 may contact the first contact surface 102 of the process chamber 110. For example, when the door 120 closes the opening 200, the first contact surface 102 and the second contact surface 122 may contact each other. In an embodiment, the second contact surface 122 may have a size corresponding to a size of the first contact surface 102 so that the second surface 122 contacts the first contact surface 102 (e.g., completely or substantially completely contacts the first contact surface 102).

In an embodiment, the door 120 may have a width that decreases from an upper portion of the door 120 to a lower portion of the door 120 in a cross-sectional view (e.g., a direction from an upper portion to a lower portion being defined by the third direction DR3). For example, the width of the upper portion of the door 120 in the first direction DR1 may be greater than the width of the lower portion of the door 120 in the first direction DR1. In some embodiments, the cross-section may be a cross-section that does not include a concaved groove 220 and is a cross-section that cuts the door 120 along a line parallel to the first direction DR1. For example, the door 120 may have a shape of an upper-wide and a lower-narrow plane in which the width of the upper portion is greater than the width of the lower portion.

In an embodiment, the second contact surface 122 may be inclined obliquely with respect to the normal direction perpendicular (e.g., substantially perpendicular) to the substrate SUB. For example, the direction in which the second contact surface 122 is inclined may correspond to the direction in which the first contact surface 102 is inclined. In some embodiments, when the first contact surface 102 and the second contact surface 122 contact each other, a direction in which the second contact surface 122 is inclined may be a diagonal direction between an opposite direction of the first direction DR1 and the third direction DR3.

The concaved groove 220 corresponding to the opening 200 may be defined in the door 120. The concaved groove 220 may be concaved from the second contact surface 122 toward an inside of the door 120. When the first contact surface 102 and the second contact surface 122 contact each other, the opening 200 and the concaved groove 220 may be connected to each other. In an embodiment, in a cross-section, the concaved groove 220 may have a ‘C’ shape. For example, the cross-section may be a cross-section that includes the concaved groove 220 and is obtained by cutting the door 120 along a line parallel to the first direction DR1. However, shape of the concaved groove 220 according to embodiments of the present disclosure may not be limited thereto, and the concaved groove 220 may have various suitable shapes.

The door driver 130 may move the door 120. For example, the door driver 130 may move the door 120 away from the process chamber 110 to open the opening 200. In some embodiments, the door driver 130 may move the door 120 toward the process chamber 110 to close the opening 200. The door driver 130 may be connected to the door 120 or be formed integrally with the door 120 to move the door 120.

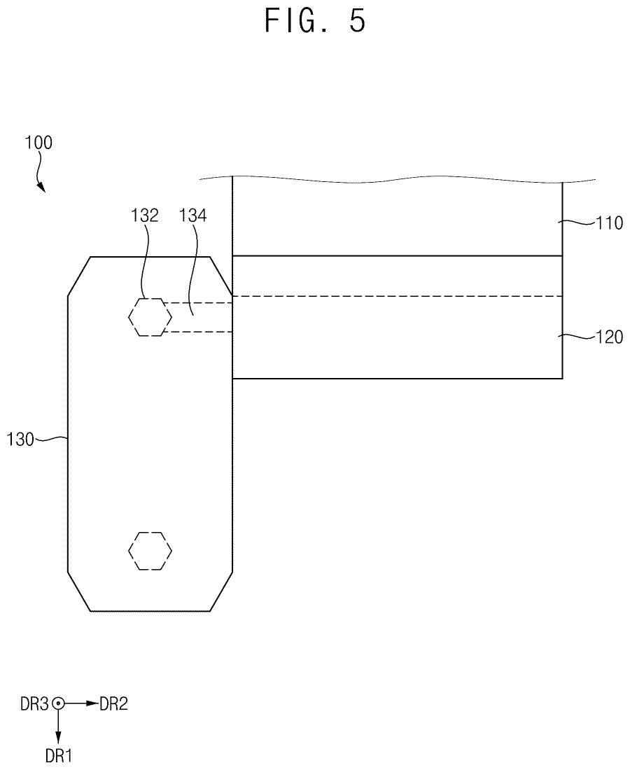

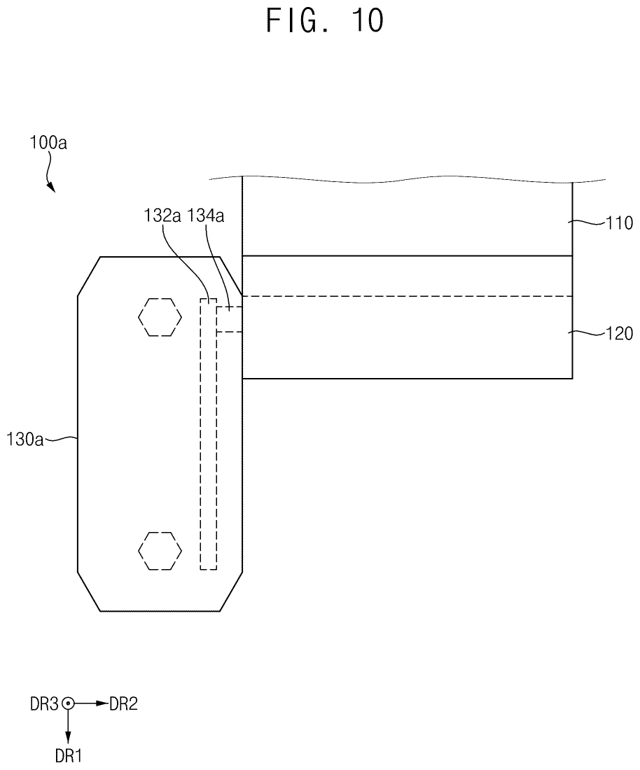

In an embodiment, the door driver 130 may include a driving motor. For example, the driving motor may automatically move the door 120. In some embodiments, before a worker performs maintenance work, the driving motor may automatically operate to move the door 120 away from the process chamber 110. A description of the method by which the door driver 130 moves the door 120 is described in detail with reference to FIG. 5 and FIG. 10.

The deposition source 140 may store and preserve the raw material. In some embodiments, the deposition source 140 may evaporate the raw material. For example, the deposition source 140 may include a crucible that may store and preserve the raw material. In some embodiments, the deposition source 140 includes a heating part, and the heating part may spray the deposition material onto the substrate SUB by heating the raw material.

The heating part may be adjacent to the crucible and transfer heat to the crucible. In an embodiment, the heating part may have a coil shape. In some embodiments, the heating part may generate heat in a resistance manner (e.g., an electrical resistance manner) and/or in an electromagnetic induction manner by using power supplied from the outside and/or inside of the process chamber 110.

The deposition source 140 may move in a direction parallel to the substrate SUB within the process chamber 110 (e.g., the first direction DR1 and/or the second direction DR2). Accordingly, the deposition source 140 may spray the deposition material toward a set or specific portion of the substrate SUB or evenly (e.g., substantially evenly) spray the deposition material toward the substrate SUB. In an embodiment, the deposition source 140 may include a nozzle capable of spraying the deposition material.

Before the opening 200 is opened by the door 120, the deposition source 140 may move toward the opening 200. For example, the deposition source 140 may move to the one side surface of the process chamber 110 adjacent to the door 120 for maintenance. After the opening 200 is opened by the door 120, the deposition source 140 may have at least a portion of an upper surface 142 exposed through the opening 200. For example, when the opening 200 is opened by the door 120, a worker located outside the process chamber 110 may easily access the deposition source 140 through the opening 200. In some embodiments, the worker may observe at least a portion of the upper surface 142 of the deposition source 140 from the outside of the process chamber 110.

The source moving part 150 may move the deposition source 140. For example, the source moving part 150 may move the deposition source 140 in the first direction DR1 and/or the second direction DR2. In some embodiments, the deposition source 140 is coupled to the source moving part 150, and the source moving part 150 may move the deposition source 140 so that the deposition source 140 faces a set or specific position of the substrate SUB. The source moving part 150 may include a guide rail, a motor, and/or the like to move the deposition source 140 in a set or specific direction. The source moving part 150 may move the deposition source 140 from the center of the process chamber 110 or another side surface opposite to the side surface (e.g., the one side surface) where the opening 200 of the process chamber 110 is defined toward the opening 200 so that at least a portion of an upper surface of the deposition source 140 is exposed by the opening 200.

In some embodiments, the source moving part 150 may fix the deposition source 140. For example, the source moving part 150 may include a fastener, such as a fixing groove and/or a fixing pin, for fixing the deposition source 140 after the deposition source 140 is moved to a set or specific position. The deposition source 140 may be fixed on the source moving part 150 by the fastener, or may be moved on the source moving part 150 when the fastener is released.

The adhesion protecting plate 160 may cover at least a portion of the inner wall surface of the process chamber 110. The adhesion protecting plate 160 may reduce contamination caused on the inner wall surface of the process chamber 110 by depositing the deposition material on the inner wall surface while the deposition process is performed. The adhesion protecting plate 160 may be a plate that is coupled to the process chamber 110 and is parallel (e.g., substantially parallel) to the inner wall surface. The adhesion protecting plate 160 may surround at least a portion of each of the deposition source 140 and the deposition source moving part 150 in the cross section. In some embodiments, the adhesion protecting plate 160 may extend from the lower portion of the process chamber 110 toward the substrate SUB. However, a shape and arrangement of the adhesion protecting plate 160 according to embodiments of the present disclosure may be examples and the present disclosure is not limited thereto, and the shape and arrangement of the adhesion protecting plate 160 may have various suitable shapes and arrangements.

The fixing part 170 has a surface on which the substrate SUB may be fixed, and may support and fix the substrate SUB. In an embodiment, the fixing part 170 may move in the up-and-down direction (e.g., in the third direction DR3 and an opposite direction of the third direction DR3) in response to a loading time of the deposition material, an unloading time, and/or a performing time of the deposition process. In some embodiments, as an example, the fixing member 170 may be provided to include a heating member or may be connected to a heating member to heat and maintain the deposition material placed on the fixing member 170 at a preset temperature.

However, the components included in the deposition apparatus 100 according to the embodiments of the present disclosure may not be limited thereto, and the deposition apparatus 100 may further include various suitable components for performing the deposition process.

FIG. 5 is a plan view illustrating a portion of the deposition apparatus of FIG. 1.

Referring to FIG. 5, in an embodiment, the door driver 130 may include a shaft 132 parallel (e.g., substantially parallel) to the third direction DR3. The door 120 may be connected to the shaft 132 through a connector 134.

In an embodiment, the connector 134 may be a part of the door 120. For example, the connector 134 may be a part of the connector 134 that extends from one side of the door 120 and engages with the shaft 132.

In an embodiment, the connector 134 may be a part of the door driver 130. For example, the connector 134 may be a portion of the door driver 130 that extends from the shaft 132 toward the door 120 and engages with the door 120. However, the connector 134 according to embodiments of the present disclosure may not be limited thereto, and may correspond to various suitable types (or kinds) of components that connect the door 120 and the door driver 130.

In an embodiment, the door driver 130 may open and close the opening 200 by rotating the door 120. For example, the door 120 may rotate around the shaft 132 as a center and the connector 134 as the radius. In some embodiments, the door 120 may rotate away from the process chamber 110 around the shaft 132 as the center to open the opening 200. In some embodiments, the door 120 may rotate toward the process chamber 110 around the shaft 132 as the center to close the opening 200.

In an embodiment, the shaft 132 to which the connector 134 is connected may be adjacent to the door 120. For example, the shaft 132 to which the connector 134 is connected may be adjacent to one side of the door driver 130 facing in an opposite direction of the first direction DR1. However, the position of the shaft 132 according to the embodiments of the present disclosure may not be limited thereto, and the shaft 132 to which the connector 134 is connected may have various suitable arrangements. For example, the shaft 132 to which the connector 134 is connected may not be adjacent to the door 120, and the shaft 132 to which the connector 134 is connected may be adjacent to the other side of the door driver 130 facing the first direction DR1.

As described above, in the deposition apparatus 100 according to the embodiments of the present disclosure, the door 120 may open and close the opening 200 defined on the one side of the process chamber 110. In some embodiments, when the door 120 opens the opening 200, the deposition source 140 may be exposed through the opening 200. Accordingly, when performing maintenance work on the deposition apparatus 100, because the worker may easily perform the maintenance work periodically from the outside the process chamber 110, an efficiency of the maintenance work on the deposition apparatus 100 may be improved.

In some embodiments, because a guide rail, a moving cart, and/or the like, for accessing the process chamber 110 are not required separately, the efficiency of the maintenance work on the deposition apparatus 100 may be further improved, and the maintenance work time may be shortened.

In some embodiments, in a cross-sectional view, the door 120 may have a width which decreases from an upper portion of the door 120 to a lower portion of the door 120, and the process chamber 110 may have a width which increases from an upper portion of the process chamber 110 to a lower portion of the process chamber 110. Accordingly, because the opening 200 may be easily opened and closed using the door 120, the efficiency of the maintenance work on the deposition apparatus 100 may be further improved.

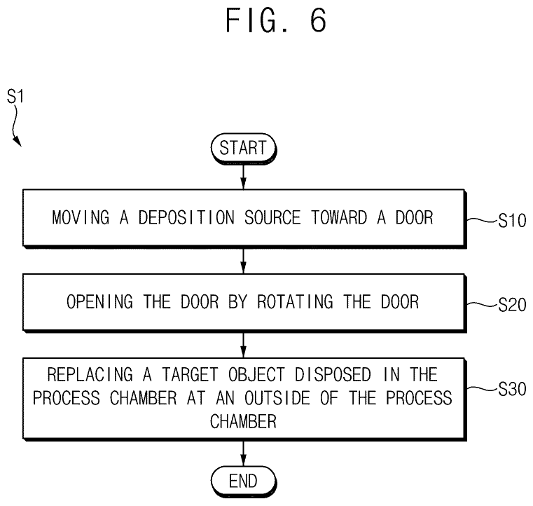

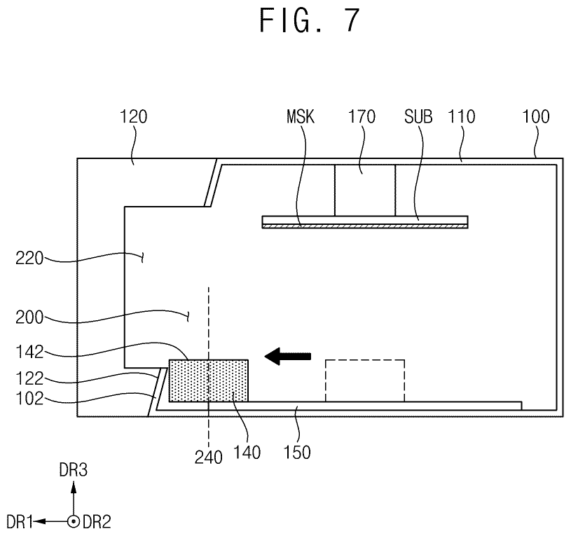

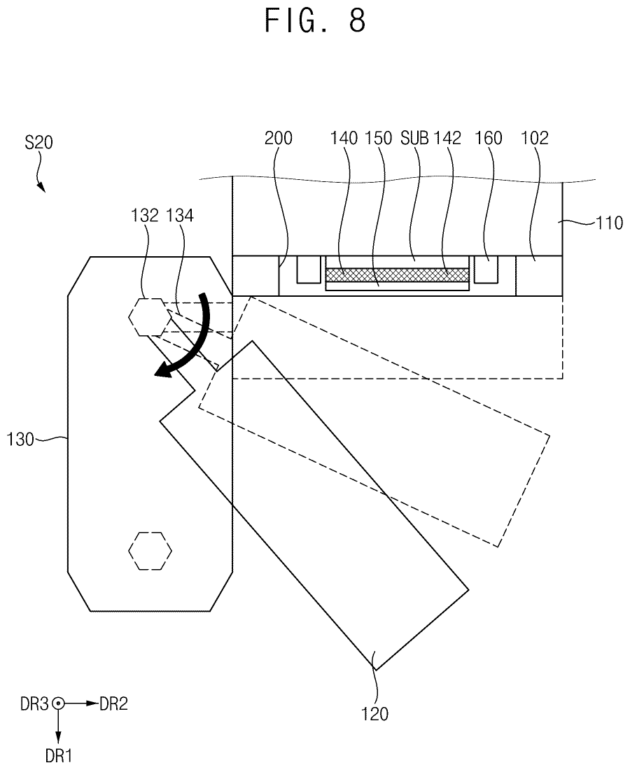

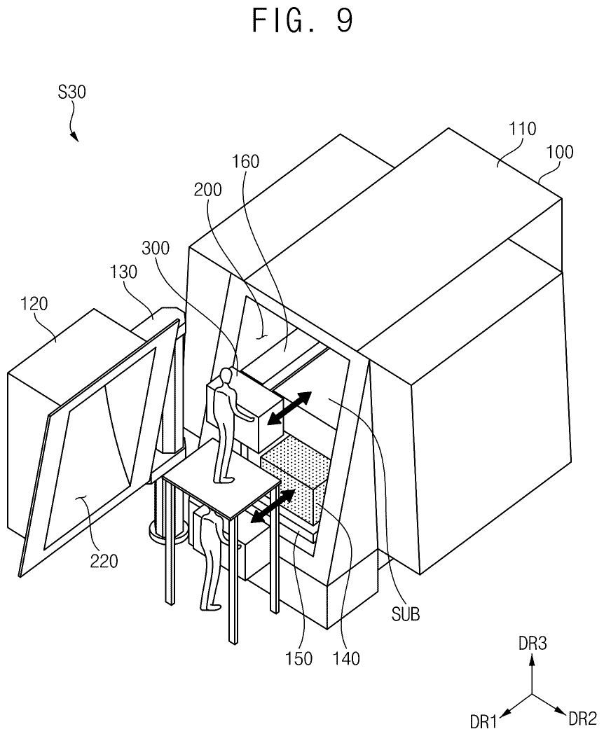

FIG. 6 is a flow chart illustrating a method of maintaining the deposition apparatus of FIG. 1. FIG. 7 is a cross-sectional view illustrating a moving of the deposition source toward the door. FIG. 8 is a plan view illustrating an opening of the opening by rotating the door. FIG. 9 is a view illustrating a replacing of the target object provided in the process chamber at the outside of the process chamber.

Referring to FIGS. 6-9, a method of maintaining the deposition apparatus S1 of an embodiment of the present disclosure may include moving the deposition source 140 toward the door 120 S10, opening the opening 200 by rotating the door 120 S20, and replacing a target object provided in the process chamber 110 at an outside of the process chamber 110 S30. In an embodiment, the method of maintaining the deposition apparatus S1 may be a method performing a maintain work on the deposition apparatus 100 of FIG. 1. However, a target of the method S1 may not be limited to thereto.

The moving of the deposition source 140 toward the door 120 S10 may be performed after the deposition process of heating the deposition source 140 to deposit the deposition material on the substrate SUB is completed. For example, while the deposition process is performed in the process chamber 110, the moving of the deposition source 140 toward the door 120 S10 may not be performed.

In the moving of the deposition source 140 toward the door 120 S10, the deposition source 140 may be moved using the source moving part 150. For example, the deposition source 140 may be moved in a direction parallel (e.g., substantially parallel) to the substrate SUB (e.g., the first direction DR1 and/or the second direction DR2) using the source moving part 150.

In an embodiment, the deposition source 140 may be moved so that its center is exposed by the opening 200. For example, when the opening of the opening 200 by rotating the door 120 S20 is performed, the center of the deposition source 140 may be exposed to the outside the process chamber 110 by the opening 200. For example, the source moving part 150 may move the deposition source 140 toward the opening 200 in advance (e.g., before the opening 200 is opened by the door 120) so that the center of the deposition source 140 is exposed to the outside of the process chamber 110 at a time when the door 120 opens the opening 200.

The center of the deposition source 140 may be defined by a center line 240 parallel to the third direction DR3 and passing through the center of the deposition source 140. In an embodiment, the center of the deposition source 140 may be a part for storing and preserving the raw material. In some embodiments, the center of the deposition source 140 may be a part for replacing the raw material.

In the moving of the deposition source 140 toward the door 120 S10, the source moving part 150 may move the deposition source 140 to a position where the deposition source 140 may be supported. For example, the source moving part 150 may move the deposition source 140 so that the center of the deposition source 140 contacts an end (e.g., an one end) of the source moving part 150. In some embodiments, the source moving part 150 may move the deposition source 140 so that the center line 240 is not located in the first direction DR1 from the end of the source moving part 150 facing the first direction DR1. For example, the center line 240 may be located in the opposite direction of the first direction DR1 from the end of the source moving part 150 or may overlap with the end.

However, in the moving the deposition source 140 toward the door 120 S10 according to the embodiments of the present disclosure, a maximum position to which the deposition source 140 moves may not be limited thereto, and a position to which the deposition source 140 is supported may suitably vary depending on a shape of the source moving part 150. For example, because the center of gravity of the deposition source 140 and the source moving part 150 may suitably vary depending on the shape of the source moving part 150, the source moving part 150 may have a shape that may support the deposition source 140 even when the position of the center line 240 is spaced apart from the source moving part 150 in the first direction DR1.

The opening of the opening 200 by rotating the door 120 S20 may be performed after the moving of the deposition source 140 toward the door 120 S10 is completed. In the opening of the opening 200 by rotating the door 120 S20, the door 120 may be rotated away from the door 120 with the shaft 132 as the center. For example, the door 120 may be rotated counterclockwise by the door driver 130 to open the opening 200. In some embodiments, the door 120 may be rotated clockwise by the door driver 130 to close the opening 200.

The door 120 may be opened so that the upper surface of the deposition source 140 is exposed. In an embodiment, in the opening of the opening 200 by rotating the door 120 S20, the opening 200 may be opened so that the central portion of the deposition source 140 is exposed. In some embodiments, as the door 120 opens the opening 200, the first contact surface 102, the source moving part 150, the adhesion protecting plate 160, and/or the like, may be exposed. Accordingly, the opening 200 may not overlap the process chamber 110 in a plan view. A portion illustrated by a dotted line in FIG. 8 illustrates a trajectory of the door 120 moving while the door 120 opens the opening 200. However, the components included in the deposition apparatus 100 exposed by a movement of the door 120 according to the embodiments of the present disclosure may not be limited thereto. The trajectory of the door 120 illustrated by the dotted line may be an example and may not be limited thereto, and the door 120 may open the opening 200 along various suitable trajectories.

In the replacing of the target object provided in the process chamber 110 from the outside of the process chamber 110 S30, the target object may be an object that needs to be replaced for maintenance work. For example, the target object may include the raw material stored in the deposition source 140 and/or the contaminated adhesion protecting plate 160. However, the target object according to the embodiments of the present disclosure may not be limited thereto.

In an embodiment, when the raw material stored in the deposition source 140 is exhausted or insufficient, the work of replacing the raw material with a new one may be performed by the worker. In an embodiment, in the replacing of the target object provided in the process chamber 110 from the outside of the process chamber 110 S30, the work of replacing the adhesion protecting plate 160 contaminated by the deposition material deposition with a new adhesion protecting plate 160 may be performed by the worker.

The worker may perform the replacement work from the outside of the process chamber 110. For example, during the replacing of the target object disposed in the process chamber 110 from the outside of the process chamber 110 S30, the worker may perform the replacement work of the raw material stored in the deposition source 140 whose center is exposed by the opening 200 from outside the process chamber 110. In some embodiments, during the replacing of the target object provided in the process chamber 110 from the outside of the process chamber 110 S30, the worker may perform the replacement of the contaminated deposition plate 160 from outside the process chamber 110.

As described above, in the method S1 according to an embodiment of the present disclosure, the deposition source 140 is moved toward the door 120 so that the center of the deposition source 140 is exposed by the opening 200, and the target object provided in the process chamber 110 may be replaced from the outside of the process chamber 110. Accordingly, the worker may perform the maintenance work from the outside of the process chamber 110 without directly entering the inside of the process chamber 110, so that the efficiency of the maintenance work of the large-sized deposition apparatus 100 may be improved. In some embodiments, a gas mask, gas suit, and/or the like, worn separately by the worker when entering the process chamber 110 while performing the method S1 is not required. Accordingly, maintenance costs and time may be reduced through the method S1.

FIG. 10 is a perspective view illustrating a portion a deposition apparatus according to another embodiment of the present disclosure.

A deposition apparatus 100a described with reference to FIG. 10 may be substantially a same as or similar to the deposition apparatus 100 described with reference to FIG. 1 except for the door driver 130a. Hereinafter, any content overlapping with the content described with reference to FIG. 1 and FIG. 5 may not be repeated or may be simplified.

Referring to FIG. 10, the deposition apparatus 100a may include a door driver 130a. In an embodiment, the door driver 130a may slide the door 120. The door driver 130a may include a sliding guide 132a for sliding the door 120. The door 120 may be connected to the sliding guide 132a through a connector 134a.

In an embodiment, the connector 134a may be a portion of the door 120. For example, the connector 134a may be a portion of the connector 134a that extends from one side of the door 120 and engages with the sliding guide 132a.

In an embodiment, the connector 134a may be a portion of the door driver 130a. For example, the connector 134a may be a portion of the door driver 130a that extends from the sliding guide 132a toward the door 120 and engages with the door 120. However, the connector 134a according to embodiments of the present disclosure may not be limited thereto, and may correspond to various suitable types (or kinds) of components that connect the door 120 and the door driver 130a.

In an embodiment, the door driver 130a may open and close the opening 200 of FIG. 1 by slidingly moving the door 120. For example, the door driver 130a may open the opening by sliding the door 120 along the sliding guide 132a in the first direction DR1. In some embodiments, the door driver 130a may close the opening by sliding the door 120 along the sliding guide 132a in the opposite direction of the first direction DR1. For example, the door 120 may open the opening by rotating counterclockwise while sliding in the first direction DR1. In some embodiments, the door 120 may close the opening by rotating clockwise while sliding in the opposite direction of the first direction DR1.

However, the movement and rotation of the door 120 according to the embodiments of the present disclosure may not be limited thereto, and the door 120 may perform various suitable sliding movements to open and close the opening by the door driver 132a. For example, the door 120 may not rotate while sliding in the first direction DR1 or in the opposite direction of the first direction DR1. In some embodiments, the door 120 may slide in the first direction DR1 or in opposite direction of the first direction DR1 while maintaining a state parallel (e.g., substantially parallel) to the one side of the process chamber 110.

As described above, in the deposition apparatus 100a according to the embodiments of the present disclosure, the door 120 may open and close the opening 200 defined in the one side of the process chamber 110. In some embodiments, when the door 120 opens the opening 200, the deposition source 140 may be exposed through the opening 200. Accordingly, when performing maintenance work on the deposition apparatus 100a, the worker may easily perform the maintenance work periodically from outside the process chamber 110, so that the efficiency of the maintenance work on the deposition apparatus 100a may be improved.

In some embodiments, because a guide rail, a moving carriage, and/or the like, for accessing the process chamber 110 are not required separately, the efficiency of the maintenance work of the deposition apparatus 100a may be further improved, and the maintenance work time may be shortened.

In some embodiments, in a cross-sectional view, the door 120 may have a width which decreases from the upper portion of the door 120 to the lower portion of the door 120, and the process chamber 110 may have a width which increases from the upper portion of the process chamber 110 to the lower portion of the process chamber 110. Accordingly, because the opening 200 may be easily opened and closed using the door 120, the efficiency of the maintenance work of the deposition apparatus 100a may be further improved.

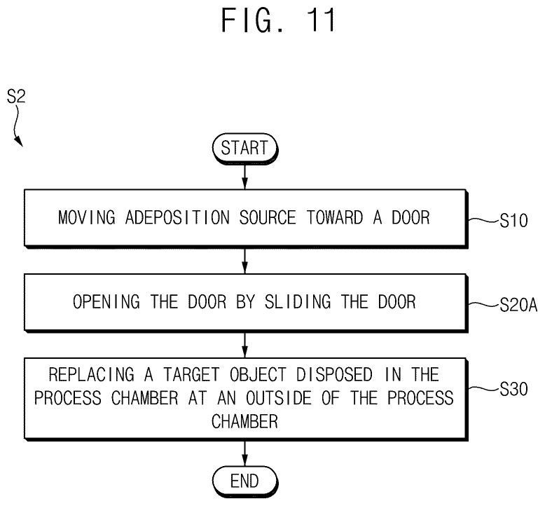

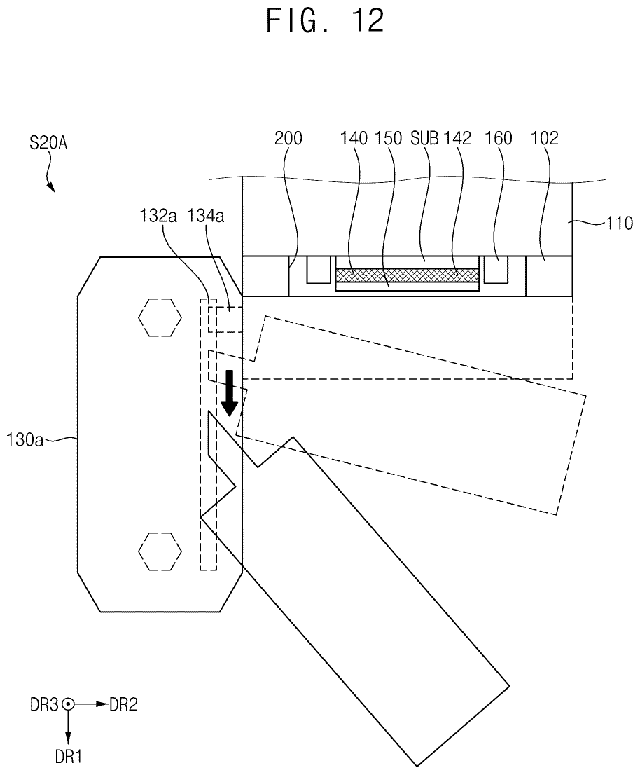

FIG. 11 is a flow chart illustrating an embodiment of a method of maintaining the deposition apparatus of FIG. 10. FIG. 12 is a plan view illustrating an opening of the opening by sliding the door.

A method of maintaining the deposition apparatus S2 described with reference to FIGS. 11-12 may be substantially a same as or similar to the method of maintaining the deposition apparatus S1 described with reference to FIGS. 6-9, except for the opening of the opening 200 by sliding the door 130a S20A. Hereinafter, any content overlapping with the content described with reference to FIGS. 6-9 may not be omitted or may be simplified.

Referring to FIGS. 11-12, the method S2 according to embodiments of the present disclosure may include the moving of the deposition source 140 toward the door 120 S10, the opening of the opening 200 by sliding he door 130a S20A, and the replacing of the target object provided in the process chamber 110 from the outside of the process chamber 110 S30. In an embodiment, the method S2 may be a method of performing maintenance work on the deposition apparatus 100a of FIG. 10. However, the target of the method S2 according to embodiments of the present disclosure may not be limited thereto.

In the opening of the opening 200 by sliding he door 130a S20A, the door 120 may slide in a direction away from the door 120 along the sliding guide 132a. For example, the door 120 may move in a first direction DR1 by the door driver 130a to open the opening 200, or may move in the opposite direction of the first direction DR1 to close the opening 200. In some embodiments, as the connector 134a connected to each of the sliding guide 132a and the door 120 moves in the first direction DR1, the door 120 also slides in the first direction DR1, and as the connector 134a moves in the opposite direction of the first direction DR1, the door 120 may also slide in the opposite direction of the first direction DR1.

However, a method in which the door moving part (e.g., the door moving part 130, 130a of FIG. 1 and FIG. 10, respectively) according to embodiments of the present disclosure moves the door 120 may not be limited to rotation, sliding, and/or the like, and the door 120 may be moved in various suitable ways to open and close the opening 200.

As described above, in the method S2 according to an embodiment of the present disclosure, the deposition source 140 is moved toward the door 120 so that the center of the deposition source 140 is exposed by the opening 200, and the target product provided in the process chamber 110 may be replaced from the outside of the process chamber 110. Accordingly, the worker may perform maintenance work outside the process chamber 110 without directly entering the inside of the process chamber 110, so that the efficiency of the maintenance work of the large-scale deposition apparatus 100a may be improved. In some embodiments, a gas mask, a gas suit, etc. to be worn by the worker when entering the inside of the process chamber 110 while performing the method S2 is not separately required. Accordingly, the maintenance cost and time may be reduced through the method S2.

The apparatus and the method according to embodiments may be applied to a display device included in a computer, a notebook, a mobile phone, a smartphone, a smart pad, a PMP, a PDA, an MP3 player, and/or the like.

Although the apparatuses and the methods according to embodiments have been described with reference to the drawings, the illustrated embodiments are examples, and may be modified and changed by a person having ordinary knowledge in the relevant technical field without departing from the technical spirit described in the following claims, and equivalents thereof.

What is claimed is:

1. A deposition apparatus comprising:
a process chamber that provides a space to process a substrate, and comprises a side surface in which an opening is defined;
a door configured to open or close the opening of the process chamber; and
a deposition source configured to supply a deposition material to the substrate in the process chamber, and comprising an upper surface of which at least a portion is exposed through the opening when the opening is opened by the door.

2. The deposition apparatus as claimed in claim 1, further comprising:
a door driver configured to move the door.

3. The deposition apparatus as claimed in claim 2, wherein the door driver opens or closes the opening by rotating the door.

4. The deposition apparatus as claimed in claim 2, wherein the door driver opens or closes the opening by sliding the door.

5. The deposition apparatus as claimed in claim 1, wherein a first contact surface of the process chamber adjacent to the opening contacts a second contact surface of the door when the opening is closed by the door.

6. The deposition apparatus as claimed in claim 5, wherein each of the first contact surface and the second contact surface is inclined obliquely with respect to a normal direction of the substrate, in a cross-sectional view.

7. The deposition apparatus as claimed in claim 5, wherein a concave groove concaved from the second contact surface toward an inside of the door is defined in the door.

8. The deposition apparatus as claimed in claim 7, wherein the concave groove and the opening are connected to each other when the opening is closed by the door.

9. The deposition apparatus as claimed in claim 1, wherein a width of the door decreases from an upper portion of the door to a lower portion of the door, in a cross-sectional view.

10. The deposition apparatus as claimed in claim 1, wherein a width of the process chamber increases from an upper portion of the process chamber to a lower portion of the process chamber, in a cross-sectional view.

11. The deposition apparatus as claimed in claim 1, further comprising:
a source moving part configured to move the deposition source in a direction parallel to the substrate in the process chamber.

12. The deposition apparatus as claimed in claim 11, wherein the source moving part moves the deposition source toward the door when the opening is opened by the door.

13. A deposition apparatus comprising:
a process chamber that provides a space to process a substrate, and comprising a side surface in which an opening is defined;
a door configured to open or close the opening of the process chamber, and having a width which gradually decreases from an upper portion of the door to a lower portion of the door in a cross-sectional view; and
a deposition source configured to supply a deposition material to the substrate in the process chamber.

14. The deposition apparatus as claimed in claim 13, wherein a width of the process chamber increases from an upper portion of the process chamber to a lower portion of the process chamber.

15. The deposition apparatus as claimed in claim 13, wherein at least a portion of an upper surface of the deposition source is exposed through the opening when the opening is opened by the door.

16. A method of maintaining the deposition apparatus, the method comprising:
moving a deposition source configured to supply a deposition material to a substrate in a process chamber toward a door contacting a side surface of the process chamber;
opening an opening defined in the side surface of the process chamber by using the door; and
replacing a target object provided in the process chamber through the opening at an outside of the process chamber.

17. The method as claimed in claim 16, wherein in the opening of the opening,
the door is opened so that a center portion of the deposition source is exposed.

18. The method as claimed in claim 17, wherein in the moving of the deposition source toward the door, the deposition source is moved in a direction parallel to the substrate using a source moving part coupled to the deposition source,
wherein in the opening of the opening, the source moving part supports the center portion of the deposition source.

19. The method as claimed in claim 16, wherein in the opening of the opening, the opening is opened by rotating the door.

20. The method as claimed in claim 16, wherein in the opening of the opening, the opening is opened by sliding the door.
